(19) United States
(12) Patent Application Publication
(10) Pub. No.: US 2005/0185802 A1
(43) Pub. Date: Aug. 25, 2005

(54) Bass boost circuit and bass boost processing program

(75) Inventor: Masahiro Yoshida, Osaka (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/063,613

(22) Filed: Feb. 24, 2005

(30) Foreign Application Priority Data
Feb. 24, 2004 (JP) 2004-048011

(51) Int. Cl. H03G 5/00; H03G 3/00

(52) U.S. Cl. 381/98; 381/61

(57) ABSTRACT

There is provided a first adder which synthesizes input audio signals in a plurality of channels, a first band-pass filter which transmits only a signal in a predetermined frequency band in the audio signals synthesized by the first adder, and a full-wave rectification circuit which generates an even-order harmonic signal of the audio signal transmitted from the first band-pass filter. A lower limit frequency of the first band-pass filter is set at a value such that a frequency interval between adjacent orders of the even-order harmonic signal generated by the full-wave rectification circuit is not less than a critical bandwidth of a signal frequency band from a reproduction lower limit frequency of a speaker to be used to an upper limit frequency of a harmonic wave to be used to boost the bass.

### BACKGROUND OF THE INVENTION

1. Field of the Invention

The present invention relates to a bass boost circuit and a bass boost processing program in which a bass can be boosted when a small speaker or a headphone having a low bass reproducing ability is used.

2. Description of the Background Art

It is known that when a sound comprising signals 2f, 3f, 4f, . . . which are harmonics of a signal of a reference frequency f is generated, there is a psychological phenomenon in which even when the signal of the reference frequency f is not contained in that sound, the sound of the frequency f seems to be reproduced.

In addition, as a method of generating the harmonic, although there are various kinds of methods, the most simple method is such that even-order harmonics are generated by performing full-wave rectification for the signal of the reference frequency.

The bass reproducing ability is limited by capacity of a speaker mainly. Therefore, a sufficient bass reproducing ability cannot be provided in a small speaker used in a television and the like. As a method of solving that problem, there is a method of enabling a human to sense a reference frequency signal which cannot be reproduced by the speaker, by the psychological phenomenon provided with a harmonic signal. Japanese Unexamined Patent Publication No. 08-237800 discloses technique in which a bass is boosted by performing the full-wave rectification only for a bass component which cannot be reproduced by a speaker in an inputted audio signal to generate the even-order harmonics of the bass component, amplifying the second harmonic in the generated harmonic and adding it to the inputted audio signal.

However, even if the bass can be recognized, there is not provided natural sound in this conventional technique because of the following reasons.
(1) A reproduction lower limit frequency is 150 to 180 Hz even in a speaker used in a normal large TV. Therefore, although the harmonic is generated for instrument sound, when the harmonic of the instrument sound is reproduced, unnatural sound is provided. In addition, when a low-frequency harmonic is generated, the harmonic becomes an inharmonic tone. When the harmonic is generated for a broadband reference tone, various kinds of harmonic components are mixed and the bass cannot be recognized in some cases.
(2) When only the harmonic is amplified and added to the input audio signal in music, unnatural sound is provided. In addition, since envelop characteristics of the harmonic generated by the full-wave rectification are fixed, natural sound cannot be provided.

### SUMMARY OF THE INVENTION

It is an object of the present invention to provide a bass boost circuit and a bass boost processing program in which a natural and consonant harmonic can be provided and a natural reproduction sound can be provided.

In addition, it is an object of the present invention to provide a bass boost circuit and a bass boost processing program in which the second harmonic is prevented from being generated for both reference wave and its harmonic so that a natural reproduced sound can be provided.

Furthermore, it is an object of the present invention to provide a bass boost circuit and a bass boost processing program in which a sense of discomfort due to the harmonic can be prevented.

A bass boost circuit according to the present invention comprises a first adder which synthesizes input audio signals in a plurality of channels, a first band-pass filter which transmits only a signal in a predetermined frequency band in the audio signals synthesized by the first adder, a full-wave rectification circuit which generates an even-order harmonic signal of the audio signal transmitted from the first band-pass filter, and an output signal generation circuit which generates an output signal in which a bass is boosted every channel, based on the harmonic signal generated by the full-wave rectification circuit and the input audio signal of the each channel, and it is characterized in that a lower limit frequency of the first band-pass filter is set at a value such that a frequency interval between adjacent orders of the even-order harmonic signal generated by the full-wave rectification circuit is not less than a critical bandwidth of a signal frequency band from a reproduction lower limit frequency of a speaker to be used to an upper limit frequency of a harmonic wave to be used to boost the bass.

It is preferable that an upper limit frequency of the first band-pass filter is set at a value which is not more than a double of the lower limit frequency of the first band-pass filter.

For example, the output signal generation circuit comprises a low-pass filter which cuts a signal in a high frequency band which exceeds the upper limit frequency of the harmonic wave to be used to boost the bass, in the harmonic signals generated by the full-wave rectification circuit, a plurality of second adders each of which is provided every channel and adds the harmonic signal transmitted from the low-pass filter to the input audio signal at each channel, a plurality of high-pass filters each of which is provided every channel and cuts a signal in a low frequency band which cannot be reproduced by the speaker to be used, in output signals from the second adder corresponding to the channel, a plurality of amplifiers each of which is provided every channel and amplifies a signal in a low frequency band in signals transmitted from the high-pass filter corresponding to the channel, and a plurality of third adders each of which is provided every channel and synthesizes a signal transmitted from the high-pass filter corresponding to the channel, with an output signal of the amplifier corresponding to the channel.

In addition, for example, the output signal generation circuit comprises a second band-pass filter which cuts a signal in a high frequency band which exceeds the upper limit frequency of the harmonic wave to be used to boost the bass, and cuts a signal in a low frequency band which cannot be reproduced by the speaker to be used in the harmonic signals generated by the full-wave rectification circuit, a high-pass filter each of which is provided every channel and cuts a signal in a low frequency band which cannot be reproduced by the speaker to be used, in the input audio signals corresponding to the channel, a plurality of second adders each of which is provided every channel and adds the harmonic signal transmitted from the second band-pass filter to the audio signal transmitted from the high-pass filter corresponding to the channel, a plurality of amplifiers each of which is provided every channel and amplifies a signal in a low frequency band, in output signals of the second adder corresponding to the channel, and a plurality of third adders each of which is provided every channel and synthesizes the output signal of the second adder corresponding to the channel, with an output signal of the amplifier corresponding to the channel.

A bass boost processing program according to the present invention is performed by a computer and comprises a first step of synthesizing input audio signals of a plurality of channels, a second step of extracting only a signal in a predetermined frequency band, in the audio signals synthesized by the first step, using a first band-pass filter, a third step of generating an even-order harmonic signal of the audio signal transmitted from the first band-pass filter, and a fourth step of generating an output signal in which a bass is boosted every channel, based on the harmonic signal generated by the third step and the input audio signal at each channel, and it is characterized in that a lower limit frequency of the fist band-pass filter is set at a value such that a frequency interval between adjacent orders of the even-order harmonic signal generated by the third step is not less than a critical bandwidth of a signal frequency band from a reproduction lower limit frequency of a speaker to be used to an upper limit frequency of a harmonic wave to be used to boost the bass.

It is preferable that an upper limit frequency of the first band-pass filter is set at a value which is not more than a double of the lower limit frequency of the first band-pass filter.

For example, the fourth step comprises a fifth step of cutting a signal in a high frequency band which exceeds the upper limit frequency of the harmonic wave to boost the bass, in the harmonic signals generated by the third step, using a low-pass filter, a sixth step of adding the harmonic signal transmitted from the low-pass filter, to the input audio signal at each channel, a seventh step of cutting a signal in a low frequency band which cannot be reproduced by the speaker to be used, in signals provided by the sixth step, using a high-pass filter, every channel, an eighth step of amplifying a signal in a low frequency band in signals transmitted from the high-pass filter, every channel, and a ninth step of synthesizing a signal provided by the eighth step with a signal transmitted from the high-pass filter, every channel.

In addition, for example, the fourth step comprises a tenth step of cutting a signal in a high frequency band which exceeds the upper limit frequency of the harmonic wave to be used to boost the bass, and cutting a signal in a low frequency band which cannot be reproduced by the speaker to be used, using a second band-pass filter, in the harmonic signal generated by the third step, an eleventh step of cutting a signal in a low frequency band which cannot be reproduced by the speaker to be used, in the input audio signal corresponding to the channel, using a high-pass filter, every channel, a twelfth step of adding the harmonic signal transmitted from the second band-pass filter, to the audio signal transmitted from the high-pass filter every channel, a thirteenth step of amplifying a signal in a low frequency band in signals provided by the twelfth step every channel, and a fourteenth step of synthesizing a signal provided by the twelfth step, with a signal provided by the thirteenth step every channel.

### BRIEF DESCRIPTION OF THE DRAWINGS

FIG. 1 is a block diagram showing a constitution of a bass boost circuit according to an embodiment 1; and

FIG. 2 is a block diagram showing a constitution of a bass boost circuit according to an embodiment 2.

### DESCRIPTION OF THE PREFERRED EMBODIMENTS

Hereinafter, an embodiment of the present invention will be described with reference to the drawings.

[A] Description of Embodiment 1

[1] Description of a Bass Pseudo Reproducing Device

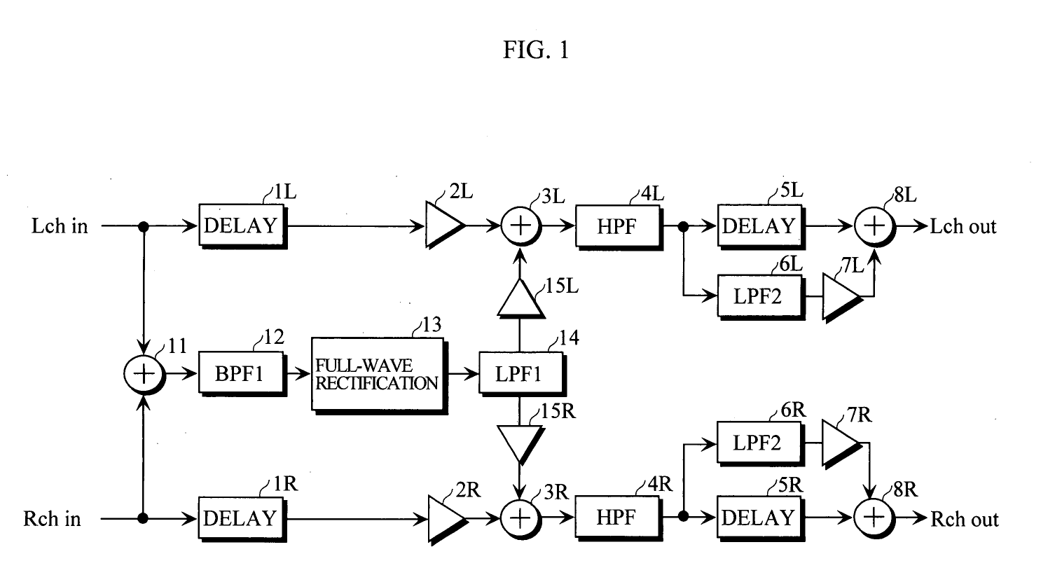

FIG. 1 shows a constitution of a bass boost circuit according to an embodiment 1.

Audio signals comprising an L channel signal (Lch in) and a R channel signal (Rch in) are inputted to the bass boost circuit. The L channel signal is transmitted to an adder 3L through a delay circuit 1L and an amplifier 2L. In addition, the L channel signal is transmitted to an adder 11 also. The R channel signal is transmitted to an adder 3R through a delay circuit 1R and an amplifier 2R. In addition, the R channel signal is also transmitted to the adder 11.

The L channel signal and the R channel signal are added in the adder 11. An output of the adder 11 is transmitted to a full-wave rectification circuit 13 through a band-pass filter (BPF1) 12 which transmits only a signal of a predetermined frequency. Characteristics and a function of the band-pass filter (BPF1) 12 will be described below. The full-wave rectification circuit 13 generates even-order harmonic signals of a signal outputted from the band-pass filter (BPF1) 12. The harmonic signal generated by the full-wave rectification circuit 13 is transmitted to a low-pass filter (LPF1) 14 to cut a high frequency component.

In addition, when the full-wave rectification is performed for any signal (sin θ), the even-order harmonics are generated as shown in the following formula (1).
abs [sin θ]=2/π+4/π×{(⅓)×sin 2θ−( 1/15)×sin 4θ+( 1/35)×sin 6θ . . . } (1)

The “abs [A]” designates an absolute value of A.

The signal outputted from the low-pass filter (LPF1) 14 is transmitted to the adder 3L through an amplifier 15L. In addition, the signal outputted from the low-pass filter (LPF1) 14 is transmitted to the adder 3R through an amplifier 15R.

An output signal of the amplifier 2L (a signal of an original sound) and an output signal of the amplifier 15L (a harmonic signal) are added in the adder 3L. An output signal of the adder 3L is transmitted to a high-pass filter (HPF)4L to cut a low frequency component. Characteristics and a function of the high-pass filter (HPF) 4L will be described below. A signal outputted from the high-pass filter (HPF) 4L is transmitted to an adder 8L through a delay circuit 5L. In addition, the signal outputted from the high-pass filter (HPF) 4L is also transmitted to an adder 8L through a low-pass filter (LPF2) 6L to cut the high frequency component and an amplifier 7L. Characteristics and a function of the low-pass filter (LPF2) 6L will be described below. The output signal of the delay circuit 5L and the output signal of the amplifier 7L are added in the adder 8L and outputted to an L channel speaker (not shown) as an output signal of an L channel (Lch out).

Similarly, the output signal of the amplifier 2R (the signal of the original sound) and the output signal of the amplifier 15R (the harmonic signal) are added in the adder 3R. An output signal of the adder 3R is transmitted to a high-pass filter (HPF) 4R to cut the low frequency component. A signal outputted from the high-pass filter (HPF) 4R is transmitted to an adder 8R through a delay circuit 5R. In addition, the signal outputted from the high-pass filter (HPF) 4R is transmitted to an adder 8R through a low-pass filter (LPF2) 6R to cut the high frequency component and an amplifier 7R. The output signal of the delay circuit 5R and the output signal of the amplifier 7R are added in an adder 8R and outputted to a R channel speaker (not shown) as an output signal of a R channel (Rch out).

In addition, the above each unit may be implemented with a hardware or may be implemented with a software.

[2] Description of Each Filter

[2-1] Description of the Band-Pass Filter (BPF1) 12

The band-pass filter (BPF1) 12 is a filter which only transmits a signal of a predetermined frequency band in the synthesized signals of the L channel signal and the R channel signal.

A reproduction lower limit frequency of the speaker is 100 Hz to 200 Hz in many cases. In addition, an upper limit frequency of the harmonic which is used to boost the bass in the harmonic signal generated by the full-wave rectification circuit 13 is about 500 Hz to 600 Hz. A critical bandwidth of a signal frequency band from the reproduction lower limit frequency (100 Hz to 200 Hz) to the upper limit frequency of the harmonic (500 Hz to 600 Hz) to be used to boost the bass is about 80 Hz to 100 Hz. When two sounds having a frequency difference of the critical bandwidth or less are generated, it is known that an inharmonic tone is generated. As the frequency difference is decreased, its inharmonic content is increased, which strikes harshly upon the ear.

Thus, according to this embodiment, the lower limit frequency of the band-pass filter (BPFL) 12 is set at 45 Hz which is about a half of the critical bandwidth of the signal frequency band from the reproduction lower limit frequency of the speaker to the upper limit frequency of the harmonic to be used to boost the bass. Thus, when the lower limit frequency of the band-pass filter (BPFL) 12 is set as described above, a frequency interval between the adjacent even orders of the even-order harmonic signal generated by the full-wave rectification circuit 13 becomes 90 Hz which corresponds to the critical band width or more, so that the inharmonic tone is not generated.

In addition, since the harmonic is originally contained in a sound of a musical instrument, when an upper limit frequency of the band-pass filter (BPF 1) 12 is set high, the second harmonic is generated in both reference wave of the instrument sound and its harmonic, so that a unnatural sound is reproduced. Thus, in this embodiment, the upper limit frequency of the band-pass filter (BPF 1) 12 is set at a value which is not more than the double of the lower limit frequency of the band-pass filter (BPF1) 12. More specifically, the upper limit frequency of the band-pass filter (BPFL) 12 is set 90 Hz which corresponds to the double of the lower limit frequency 45 Hz of the band-pass filter (BPF1) 12.

[2-2] Description of the Low-Pass Filter (LPF1) 14 (1)

The low-pass filter (LPFL) 14 is provided to cut the high frequency component in the harmonic signal generated by the full-wave rectification circuit 13. A cutoff frequency of the low-pass filter (LPFL) 14 is set at a cutoff frequency of the low-pass filters (LPF2) 6L and 6R or more.

[2-3] Description of the High-Pass Filters (HPF) 4L and 4R

Each of the high-pass filters (HPF) 4L and 4R is provided to cut a bass signal in a band which cannot be reproduced by the speaker to be used, in the signal in which the harmonic signal to boost the bass is added to the signal of the original sound. In addition, the high-pass filters (HPF) 4L and 4R prevent saturation of the signal to be amplified by the amplifiers 7L and 7R, respectively.

[2-4] Description of the Low-Pass Filters (LPF2) 6L and 6R

A cutoff frequency of the low-pass filters (LPF2) 6L or 6R is set at a cutoff frequency of the low-pass filter (LPF1) 14 or less.

The low-pass filters (LPF2) 6L and 6R cut the higher frequency components in the signals transmitted from the high-pass filters (HPF) 4L and 4R, respectively. The signal outputted from the low-pass filters (LPF2) 6L and 6R are amplified by the amplifiers 7L and 7R and then synthesized with the signals outputted from the high-pass filters (HPF) 4L and 4R, respectively.

That is, in the synthesized signals of the signal of the original sound and the harmonic signal to boost the bass, the signal in the frequency band determined by the low-pass filters (LPF2) 6L and 6R is amplified and the amplified signal (boosted signal) is synthesized with the signal of the original sound. Thus, since only the harmonic signal to boost the bass is not amplified but the predetermined band component in the synthesized signal of the signal of the original sound and the harmonic signal to boost the bass is amplified, a sense of discomfort due to the harmonics can be prevented as compared with the case where only the harmonic signal to boost the bass is amplified, so that a sense of powerful deep bass can be enhanced.

[2-5] Description of the Low-Pass Filter (LPF1) 14 (2)

When a high-order harmonic is enhanced beyond necessity, since there is provided a noisy sound, the cutoff frequency of the low-pass filter (LPF1) 14 is set such that two harmonics of n-order and (n+2)-order of the reference frequency of 90 Hz which is the upper limit frequency of the band-pass filter (BPF1) 12 can be transmitted. The “n” is the order corresponding to the harmonic having the lowest frequency in the band which is not less than the reproduction lower limit frequency of the speaker, in the even-order harmonics of the reference frequency of 90 Hz. The low-pass filter (LPF1) 14 transmits a maximum of four harmonics for the signal of 45 Hz.

For example, when a speaker which cannot reproduce a signal of 200 Hz or less is used, the harmonics of the signal having the upper limit frequency of 90 Hz which pass through the band-pass filter (BPF1) 12 are 180 Hz, 360 Hz, 540 Hz, . . . , and since the reference tone of 90 Hz can be recognized when there are fourth and sixth harmonics which can be reproduced by the speaker, the cutoff frequency of the low-pass filter (LPF1) 14 is set at 540 Hz.

In this case, the harmonics of the signal having the lower limit frequency of 45 Hz which pass through the band-pass filter (BPF1) 12 are 90 Hz, 180 Hz, 270 Hz, 360 Hz, 450 Hz, 540 Hz, . . . , and the low-pass filter (LPF1) 14 transmits the sixth, eighth, tenth and twelfth harmonics.

In addition, the characteristics of the above filters depending on a type of speaker to be used (the reproduction lower limit frequency) are shown in a table 1. In the table 1, the lower limit frequencies and the upper limit frequencies of the band-pass filter 12 are shown in BPF1, the cutoff frequencies of the low-pass filter 13 are shown in LPF1, the cutoff frequencies of the high-pass filters 4L and 4R are shown in HPF, the cutoff frequencies of the low-pass filters 6L and 6R are shown in LPF2.

TABLE 1

| Speaker type | | | |
|---|---|---|---|
| (reproduction lower | | | |
| limit frequency) | 120 Hz | 150 Hz | 180 Hz |
| BPF1 | 45 to 60 Hz | 45 to 90 Hz | 45 to 90 Hz |
| LPF1 | To 360 Hz | To 360 Hz | To 360 Hz |
| HPF | From 120 Hz | From 150 Hz | From 180 Hz |
| | or | or | or |
| | From 180 Hz | From 180 Hz | From 180 Hz |
| LPF2 | To 240 Hz | To 300 Hz | To 360 Hz |

According to the this embodiment, since the frequency band of the reference signal from which the harmonic is generated is set by the band-pass filter (BPF1) 12 at the specific band as described above, natural and consonant harmonic can be provided, so that a reproduced sound can be natural. In addition, the second harmonic is prevented from being generated in both reference wave of the instrument sound and its harmonic, a natural reproduced sound can be provided.

Furthermore, since the signal in the frequency band determined by each of the low-pass filters (LPF2) 6L and 6R is amplified after the signal of the original sound is synthesized with the harmonic signal to boost the bass, and the amplified signal (boosted signal) is synthesized with the signal of the original sound, that is, since the harmonic is boosted with the original sound, a sense of discomfort due to the harmonic can be prevented. As a result, the reference tone (bass) can be strongly recognized.

[B] Description of Embodiment 2

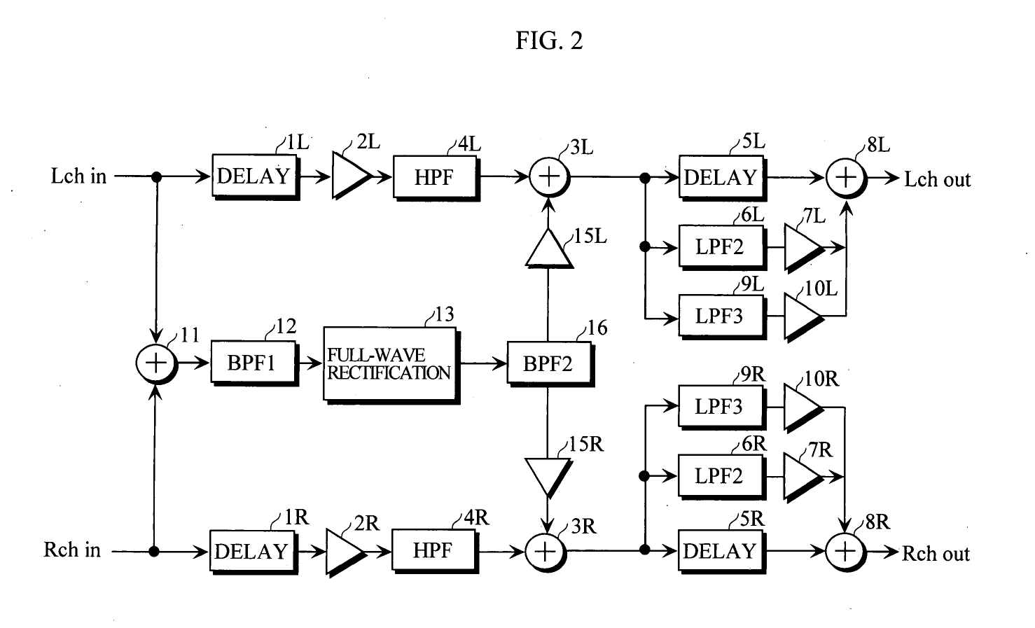

FIG. 2 shows a constitution of a boost circuit according to a second embodiment 2.

The embodiment 2 is different from the embodiment 1 in the following points.
(1) High-pass filters (HPF) 4L and 4R are provided not at the subsequent stage of adders 3L and 3R but provided at the previous stage of the adders 3L and 3R. Accordingly, instead of the low-pass filter (LPF) 14 provided at the subsequent stage of the full-wave rectification circuit 13, a band-pass filter (BPF2) 16 having functions of both low-pass filter (LPF1) 14 and high-pass filters (HPF) 4L and 4R is used.

(2) A series circuit of a low-pass filter (LPF3) 9L (9R) and an amplifier 10L (10R) is provided in parallel to a series circuit of a low-pass filter (LPF2) 6L (6R) and an amplifier 7L (7R). Characteristics of the low-pass filter (LPF2) 6L (6R) and the low-pass filter (LPF3) 9L (9R) are set as shown in a table 2, for example. In addition, when it is assumed that a gain of the amplifier 7L (7R) which amplifies a signal outputted from the low-pass filter (LPF2) 6L (6R) is G1 and a gain of the amplifier 10L(10R) which amplifies a signal outputted from the low-pass filter (LPF3) 9L (9R) is G2, it is set such that G1>G2.

TABLE 2

| Speaker type | | | |
|---|---|---|---|
| (reproduction lower limit frequency) | 120 Hz | 150 Hz | 180 Hz |
| LPF2 | To 240 Hz | To 300 Hz | To 360 Hz |
| LPF3 | To 360 Hz | To 450 Hz | To 540 Hz |

1. A bass boost circuit comprising:
a first adder which synthesizes input audio signals in a plurality of channels;
a first band-pass filter which transmits only a signal in a predetermined frequency band in the audio signals synthesized by the first adder;
a full-wave rectification circuit which generates an even-order harmonic signal of the audio signal transmitted from the first band-pass filter; and
an output signal generation circuit which generates an output signal in which a bass is boosted every channel, based on the harmonic signal generated by the full-wave rectification circuit and the input audio signal of each channel, wherein
a lower limit frequency of the first band-pass filter is set at a value such that a frequency interval between adjacent orders of the even-order harmonic signal generated by the full-wave rectification circuit is not less than a critical bandwidth of a signal frequency band from a reproduction lower limit frequency of a speaker to be used to an upper limit frequency of a harmonic wave to be used to boost the bass.

2. The bass boost circuit according to claim 1, wherein an upper limit frequency of the first band-pass filter is set at a value which is not more than a double of the lower limit frequency of the first band-pass filter.

3. The bass boost circuit according to claim 1, wherein the output signal generation circuit comprises:
a low-pass filter which cuts a signal in a high frequency band which exceeds the upper limit frequency of the harmonic wave to be used to boost the bass, in the harmonic signals generated by the full-wave rectification circuit;
a plurality of second adders each of which is provided every channel and adds the harmonic signal transmitted from the low-pass filter to the input audio signal at each channel;
a plurality of high-pass filters each of which is provided every channel and cuts a signal in a low frequency band which cannot be reproduced by the speaker to be used, in output signals from the second adder corresponding to the channel;
a plurality of amplifiers each of which is provided every channel and amplifies a signal in a low frequency band in signals transmitted from the high-pass filter corresponding to the channel, and
a plurality of third adders each of which is provided every channel and synthesizes a signal transmitted from the high-pass filter corresponding to the channel, with an output signal of the amplifier corresponding to the channel.

4. The bass boost circuit according to claim 1, wherein the output signal generation circuit comprises:
a second band-pass filter which cuts a signal in a high frequency band which exceeds the upper limit frequency of the harmonic wave to be used to boost the bass, and cuts a signal in a low frequency band which cannot be reproduced by the speaker to be used in the harmonic signals generated by the full-wave rectification circuit;
high-pass filters each of which is provided every channel and cuts a signal in a low frequency band which cannot be reproduced by the speaker to be used, in the input audio signals corresponding to the channel;
a plurality of second adders each of which is provided every channel and adds the harmonic signal transmitted from the second band-pass filter to the input audio signal transmitted from the high-pass filter corresponding to the channel;
a plurality of amplifiers each of which is provided every channel and amplifies a signal in a low frequency band, in output signals of the second adder corresponding to the channel, and
a plurality of third adders each of which is provided every channel and synthesizes the output signal of the second adder corresponding to the channel, with an output signal of the amplifier corresponding to the channel.

5. A bass boost processing program performed by a computer comprising:
a first step of synthesizing input audio signals of a plurality of channels;
a second step of extracting only a signal in a predetermined frequency band, in the audio signals synthesized by the first step, using a first band-pass filter;
a third step of generating an even-order harmonic signal of the audio signal transmitted from the first band-pass filter; and
a fourth step of generating an output signal in which a bass is boosted every channel, based on the harmonic signal generated by the third step and the input audio signal at each channel, wherein
a lower limit frequency of the fist band-pass filter is set at a value such that a frequency interval between adjacent orders of the even-order harmonic signal generated by the third step is not less than a critical bandwidth of a signal frequency band from a reproduction lower limit frequency of a speaker to be used to an upper limit frequency of a harmonic wave to be used to boost the bass.

6. The bass boost processing program according to claim 5, wherein an upper limit frequency of the first band-pass filter is set at a value which is not more than a double of the lower limit frequency of the first band-pass filter.

7. The bass boost processing program according to claim 5, wherein the fourth step comprises:
a fifth step of cutting a signal in a high frequency band which exceeds the upper limit frequency of the harmonic wave to be used to boost the bass, in the harmonic signals generated by the third step, using a low-pass filter;
a sixth step of adding the harmonic signal transmitted from the low-pass filter, to the input audio signal at each channel;
a seventh step of cutting a signal in a low frequency band which cannot be reproduced by the speaker to be used, in signals provided by the sixth step, using a high-pass filter, every channel;
an eighth step of amplifying a signal in a low frequency band in signals transmitted from the high-pass filter, every channel; and
a ninth step of synthesizing a signal provided by the eighth step with a signal transmitted from the high-pass filter, every channel.

8. The bass boost processing program according to claim 5, wherein the fourth step comprises:
a tenth step of cutting a signal in a high frequency band which exceeds the upper limit frequency of the harmonic wave to be used to boost the bass; and cutting a signal in a low frequency band which cannot be reproduced by the speaker to be used, using a second band-pass filter, in the harmonic signal generated by the third step;
an eleventh step of cutting a signal in a low frequency band which cannot be reproduced by the speaker to be used, in the input audio signal corresponding to the channel, using a high-pass filter, every channel;
a twelfth step of adding the harmonic signal transmitted from the second band-pass filter, to the audio signal transmitted from the high-pass filter every channel;
a thirteenth step of amplifying a signal in a low frequency band in signals provided by the twelfth step every channel; and
a fourteenth step of synthesizing a signal provided by the twelfth step, with a signal provided by the thirteenth step every channel.
